(19) United States
(12) Patent Application Publication
(10) Pub. No.: US 2021/0036168 A1
(43) Pub. Date: Feb. 4, 2021

(54) COMPLEMENTARY METAL-OXIDE-SEMICONDUCTOR (MOS) CAPACITOR

(71) Applicant: QUALCOMM Incorporated, San Diego, CA (US)

(72) Inventors: Ye LU, San Diego, CA (US); Gang LIU, San Diego, CA (US); Zhongze WANG, San Diego, CA (US)

(21) Appl. No.: 16/674,002

(22) Filed: Nov. 5, 2019

Related U.S. Application Data
(60) Provisional application No. 62/881,513, filed on Aug. 1, 2019.

(51) Int. Cl. H01L 29/94; H01L 29/66; H01L 27/08

(52) U.S. Cl. CPC H01L 29/94; H01L 27/0805; H01L 29/66181

(57) ABSTRACT

Aspects generally relate to a complimentary MOS capacitor with improved linearity. A complimentary MOS capacitor includes an n-type MOS capacitor and a p-type MOS capacitor coupled in parallel. The p-type MOS capacitor biased to an opposite voltage polarity of the n-type MOS capacitor.

### CLAIM OF PRIORITY UNDER 35 U.S.C. § 119

The present application claims the benefit of U.S. provisional application No. 62/881,513, entitled “COMPLEMENTARY METAL-OXIDE SEMICONDUCTOR (MOS) CAPACITOR,” filed Aug. 1, 2019, which is expressly incorporated by reference herein in its entirety.

### BACKGROUND

### Field of the Disclosure

Aspects of the disclosure relate generally to integrated circuits, and in particular, a complementary metal-oxide-semiconductor (MOS) capacitor.

### II. BACKGROUND

Capacitors are widely used in integrated circuits (IC). A typical capacitor structure is formed from two plates separated by a dielectric. In an IC, capacitors can occupy large amounts of area which is not desirable.

As the size of ICs decrease there is a need for capacitors that occupy less area and offer increased capacitance density.

### SUMMARY OF THE DISCLOSURE

The described aspects generally relate to capacitors in integrated circuits.

Aspects include a complimentary metal-oxide-silicon (MOS) capacitor. The complimentary MOS capacitor includes an n-type MOS capacitor and a p-type MOS capacitor coupled in parallel. The p-type MOS capacitor is biased to an opposite voltage polarity of the n-type MOS capacitor.

The complimentary MOS capacitor can further include a gate of the n-type MOS capacitor coupled to a gate of the p-type MOS capacitor and a source and a drain of the n-type MOS capacitor coupled to ground and a source and a drain of the p-type MOS capacitor coupled to a bias voltage source. The bias voltage source can be coupled to ground. The complimentary MOS capacitor can further include a voltage source coupled to the gate of the n-type MOS capacitor and the gate of the p-type MOS capacitor.

The complimentary MOS capacitor can be configured to be in a memory cell. For example, the memory cell can be a compute in memory (CIM) memory cell.

Another aspect includes a charge pump circuit including a plurality of MOS transistors configured as diodes, the plurality of MOS transistors coupled in series, and a complimentary MOS capacitor coupled between a node of one of the MOS transistors and a clock signal. The complimentary MOS capacitor includes a n-type MOS capacitor and a p-type MOS capacitor coupled in parallel. The p-type MOS capacitor is biased to an opposite voltage polarity of the p-type MOS capacitor.

The charge pump circuit can further include a gate of the n-type MOC capacitor coupled to a gate of the p-type MOS capacitor and a source and a drain of the n-type MOS capacitor coupled to ground and a source and a drain of the p-type MOS capacitor coupled to a bias voltage source. The bias voltage source can be coupled to ground. A voltage source can be coupled to the gate of the n-type MOS capacitor and the gate of the p-type MOS capacitor.

The charge pump circuit can be configured to be in a memory cell. For example, the memory cell can be a compute in memory (CIM) memory cell.

In one example, a charge pump circuit can include five MOS transistors configured as five diodes, the five diodes coupled in series such that a cathode of the first diode is coupled to a anode of the second diode, a cathode of the second diode is coupled to a anode of the third diode, a cathode of the third diode is coupled to a anode of the fourth diode, a cathode of the fourth diode is coupled to a anode of the fifth diode. A first complimentary MOS capacitor coupled between a cathode of the first diode and a clock signal and a third complimentary MOS capacitor coupled between a cathode of the third diode and the clock signal. A second complimentary MOS capacitor coupled between a cathode of the second diode and a clock_bar signal and a fourth complimentary MOS capacitor coupled between a cathode of the fourth diode and the clock_bar signal. A fifth complimentary MOS capacitor coupled between the cathode of the fifth diode and ground. An input signal coupled to the anode of the first diode and an output signal coupled to the cathode of the fifth diode.

Various aspect and features of the disclosure are described in further detail below.

### BRIEF DESCRIPTION OF THE FIGURES

The accompanying drawings are presented to aid in the description and illustrations of embodiments and are not intended to be limitations thereof.

FIG. 1A is a cross section diagram of a MIM capacitor structure.

FIG. 1B is a cross section diagram of a MOM capacitor structure.

FIG. 1C is a cross section diagram of a MOS capacitor structure.

FIG. 2 illustrates a typical capacitance versus voltage (C-V) curve of a n-type MOS capacitor.

FIG. 3 is a diagram of a 4 stage Dickson charge pump circuit.

FIG. 4 is a plot of output voltage of a Dickson charge pump versus a number of cycles.

FIG. 5A is a diagram illustrating a complimentary MOS capacitor structure that has improved linearity.

FIG. 5B illustrates plots of the capacitance versus voltage of an n-type MOS capacitor, a p-type MOS capacitor, and a complimentary MOS capacitor.

FIG. 6 is a plot of an output voltage versus number of cycles of an example Dickson charge pump implemented with MOM capacitors and complimentary MOS capacitors.

FIG. 7 illustrates a memory array.

FIG. 8 illustrates various electronic devices that may be include a complimentary MOS capacitor.

The drawings may not depict all components of a particular apparatus, structure, or method. Further, like reference numerals denote like features throughout the specification and figures.

### DETAILED DESCRIPTION

Aspects disclosed in the following description and related drawings are directed to specific aspects. Alternatives may be devised without departing from the scope of the invention. Additionally, well-known elements may not be described in detail, or may be omitted, so as not to obscure relevant details. Examples disclosed may be suitably included in any electronic device.

With reference now to the drawing, several exemplary aspects of the present disclosure are described. The word “exemplary” is used herein to mean “serving as an example, instance, or illustration.” Any aspect described herein as “exemplary” is not necessarily to be construed as preferred or advantageous over other aspects. Furthermore, the terminology used herein is for the purpose of describing particular embodiments and is not intended to be limiting

Capacitors are widely used in integrated circuits (IC). A typical IC includes a semiconductor substrate where active devices are formed. Above the substrate is an insulation layer, and then multiple metal layers separated by interlayer insulating layers. Portions of the metal layers are coupled together, and to the active devices by vias through the interlayer insulating layers. Capacitor structures are typical formed using the metal layers or active devices. In advanced ICs, some capacitor structures are formed using the metal layers such as metal-insulator-metal (MIM) capacitors and the metal-oxide-metal (MOM) capacitors.

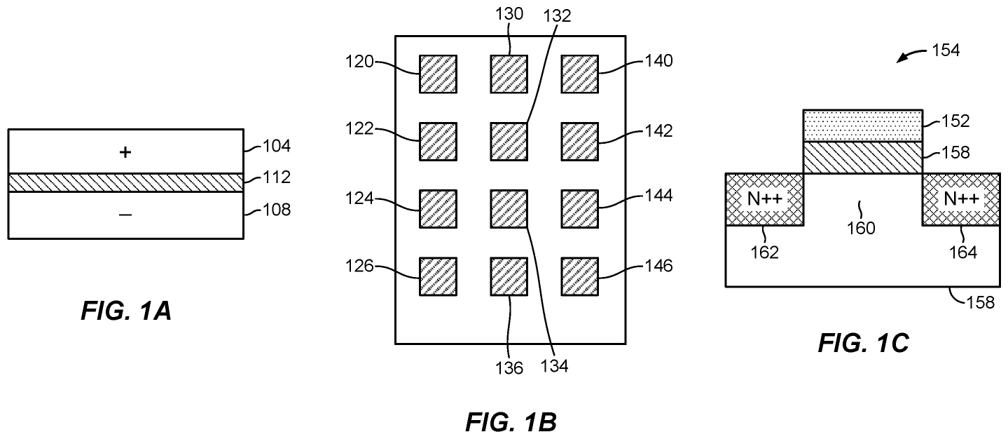

FIG. 1A is a cross section diagram of a MIM capacitor structure. As seen in FIG. 1A, a first plate of the MIM capacitor structure is formed using a portion of a metal layer 104, and a second plate of the capacitor is formed using a portion of a second metal layer 108. The first and second plates of the capacitor are separated from each other by an interlayer insulating layer 112, thereby forming the MIM capacitor.

FIG. 1B is a cross section diagram of a MOM capacitor structure. As seen in FIG. 1B, a first plate, or finger, of the MOM capacitor structure is formed from portions of multiple metal layers 120, 122, 124, and 126 connected by vias (not shown). A second plate, or finger, of the MOM capacitor structure is formed from portions of multiple metal layers 130, 132, 134, and 136 connected by vias (not shown). Insulating layers formed between, and around, the portions of the metal layers forming the first and second plates, or fingers, separate the plates, thereby forming the MOM capacitor. In the example of FIG. 1B, a third plate, or finger, of the MOM capacitor structure is formed from portions of multiple metal layers 140, 142, 144, and 146 connected by vias (not shown). Insulating layers formed between, and around, the portions of the metal layers forming the second and third plates, or fingers, separate the plates, thereby forming another MOM capacitor.

Another type of capacitor used in an IC is a metal-oxide-semiconductor (MOS) capacitor. FIG. 1C is a cross section diagram of a MOS capacitor structure. As shown in FIG. 1C a conductive gate 152 of a MOSFET transistor 154 is formed on an insulator 158 above a channel 160 between a source 162 and a drain 164 of a MOSFET transistor 154. In this configuration, the gate 152 forms one plate of the capacitor and the channel/source/drain 160, 162, and 164 form the other plate of the capacitor, the two plates separated by the insulator 158.

An advantage of the MIM and MOM capacitors is that their capacitance is linear and does not change with the voltage across the capacitor. In contrast, a MOS capacitor's capacitance changes as a function of the applied voltage.

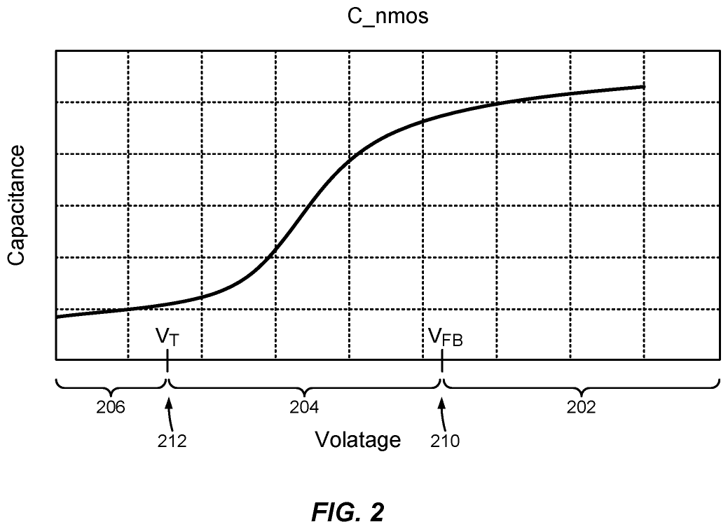

FIG. 2 illustrates a typical capacitance versus voltage (C-V) curve of a n-type MOS capacitor. The capacitance depends on the voltage that is applied to the gate (with respect to the body). As illustrated in FIG. 2 there are roughly three regions of operation separated by two voltages. The regions are described by what is happening to the semiconductor surface. In the first “accumulation” region 202, carriers of the same type as the body accumulates at the surface. In the second “depletion” region 204, the surface is devoid of any carriers leaving only a space charge or depletion layer. In the third “inversion” region 206, carriers of the opposite type from the body aggregate at the surface to “invert” the conductivity type. The two voltages that demarcate the three regimes are a Flatband Voltage (VFB) 210, which separates the accumulation region 202 from the depletion region 204, and a Threshold Voltage (VT) 212 which demarcates the depletion region 204 from the inversion region 206. The C-V curve for a p-type MOS capacitor is analogous to the n-type MOS capacitor and is essentially a mirror image of the C-V curve illustrated in FIG. 2.

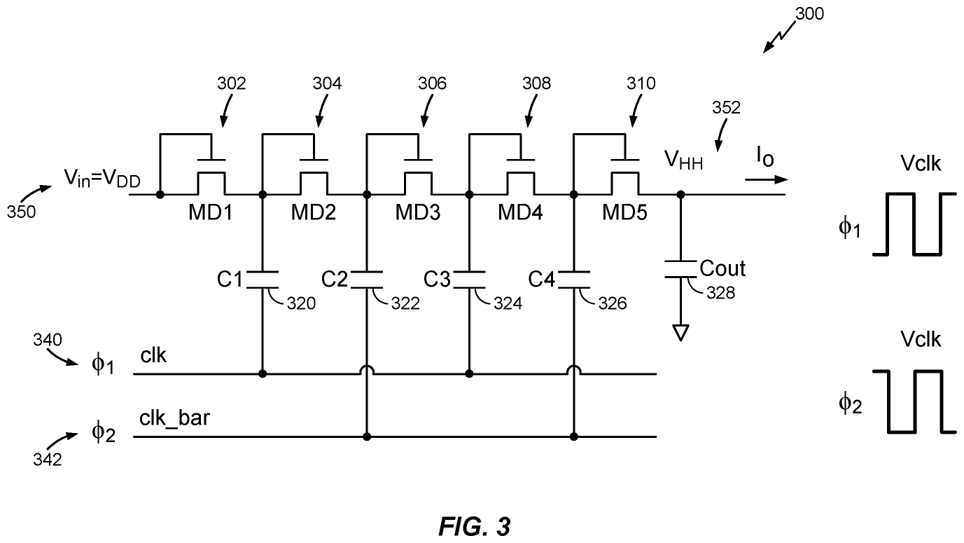

The nonlinear capacitance of MOS capacitor can have detrimental effect on some types of circuits that rely on linear capacitance for adequate performance. One such circuit is a Dickson charge pump. FIG. 3 is a diagram of a 4 stage Dickson charge pump circuit 300. In the example of FIG. 3, the Dickson charge pump 300 includes MOS transistors configured as diodes 302, 304, 306, 308, and 310 connected in series. Between the cathodes of the first and third diodes 302 and 306 a first and third capacitor 320 and 324 are coupled between the cathodes and a clock signal 340. Between the cathodes of the second and fourth diodes 304 and 308 a second and fourth capacitor 322 and 326 are coupled between the cathodes and a clock_bar signal 342. Coupled between the cathode of the fifth diode 310, the charge pump output 352, and ground is a fifth capacitor 328. An input voltage Vᵢₙ 350, equal to V_{DD}, is coupled to the anode of the first diode 302.

During operation of the Dickson charge pump 300 the input voltage Vᵢₙ 350 charges the capacitors 320, 322, 324, 326, and 328 to V_{DD}. When the clock signal 340 goes high, to a voltage of V_{DD}, the bottom plate of the first capacitor 320 rises to V_{DD} and the top plate of the first capacitor 320 is pushed up to twice V_{DD} (2V_{DD}). The higher voltage on the cathode of the first diode 302, turns the first diode “OFF” and the second diode 304 stays “ON” and the second capacitor 322 begins to charge to 2Vin. On the next clock cycle the clock signal 340 goes low and the clock_bar signal 342 goes high to a voltage level of V_{DD}, pushing the top plate of the second capacitor 322 to three times V_{DD} (3V V_{DD}). The higher voltage on the cathode of the second diode 304, turns the second diode “OFF” and the third diode 306 stays “ON” and the third capacitor 324 begins to charge to 3 V_{DD}. The switching continues pushing the charge up the chain until the fourth capacitor 326 is charged to five times V_{DD} (5V_{DD}). The fifth capacitor 328, coupled between the charge pump output 352 and ground, is not a multiplier; it is a peak detector that provides smoothing for the output signal 352 of the Dickson charge pump.

In a typical Dickson charge pump circuit, linear capacitors, such as MIM or MOM capacitors are used to obtain a more consistent charge step size versus pump cycle. MIM and MOM capacitors are large, consuming large areas of an IC. Thus, it would be beneficial to replace the MIM or MOM capacitors with MOS capacitors to reduce the amount of area used. However, as noted MOS capacitors are nonlinear which can have a detrimental impact on circuit performance.

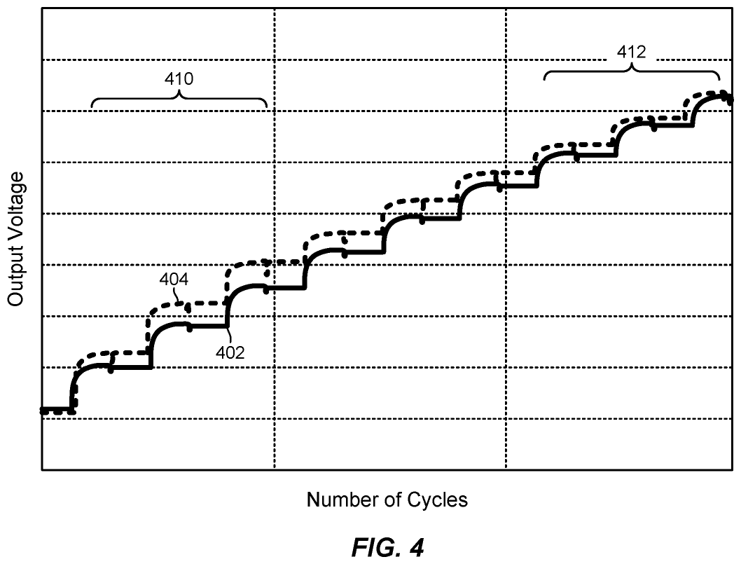

FIG. 4 is a plot of output voltage of a Dickson charge pump versus a number of cycles. In FIG. 4 a first curve 402 illustrates the output voltage of a Dickson charge pump implemented with a MOM capacitor. A second curve 404 in FIG. 4 illustrates the output voltage versus number of cycles for the Dickson charge pump implemented with MOS capacitors. The voltage step per cycle for the MOM capacitor charge pump is fairly consistent. However, as can be seen in FIG. 4, the nonlinearity of the MOS capacitor results in large voltage steps in the first few cycles 410 of the charge pump and then reduced voltage steps in later cycles 412 of the charge pump. This nonlinear performance of the charge pump is not desired.

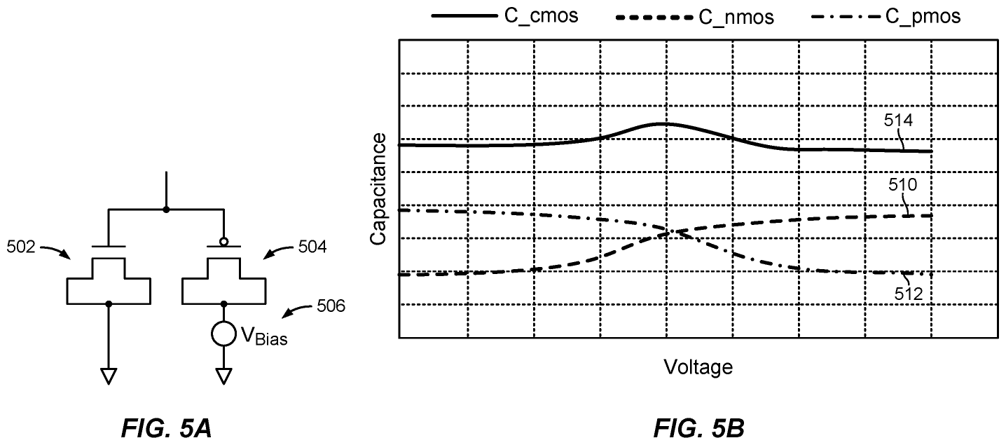

FIG. 5A is a diagram illustrating a complimentary MOS capacitor structure that has improved linearity. As shown in FIG. 5A a first NMOS transistor is configured as a n-type MOS capacitor 502. A first PMOS transistor is configured as a p-type capacitor 504. The n-type MOS capacitor 502 is coupled in parallel with the p-type MOS capacitor 504. A bias voltage 506 is coupled between the body of the p-type capacitor 504 and ground to create opposite voltage polarity between the n-type and p-type capacitors forming the complimentary MOS capacitor 504.

FIG. 5B illustrates plots of the capacitance versus voltage of an n-type MOS capacitor (C_nmos), a p-type MOS capacitor (C_pmos), and a complimentary MOS capacitor (C_cmos). As shown in FIG. 5B a first plot 510 illustrates the C-V curve of an n-type MOS capacitor. As can be seen, the C-V curve of the n-type MOS capacitor is nonlinear as the voltage across the capacitor varies. Likewise, a second plot 512 illustrates a C-V curve of a p-type MOS capacitor. As can be seen, the C-V curve of the p-type MOS capacitor is nonlinear as the voltage across the capacitor varies.

In FIG. 5B, a third plot 514 illustrates the C-V curve of the complimentary MOS capacitor. As can be seen, the C-V curve of the complimentary MOS capacitor is more linear than the n-type or p-type MOS capacitors individually. Inspection of the C-V curves for the n-type and p-type MOS capacitors shows that they roughly inversely mirror each other. Thus, in the complimentary MOS capacitor with an n-type MOS capacitor and p-type MOS capacitor having opposite voltage polarity, combined in parallel, the nonlinearity of the n-type and p-type MAS capacitors “offset” each other to produce a more linear C-V curve.

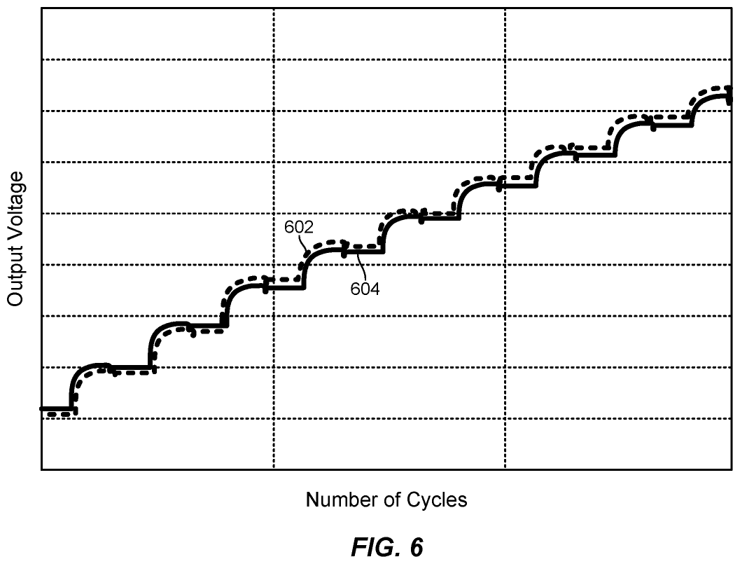

FIG. 6 is a plot of an output voltage versus number of cycles of an example Dickson charge pump implemented with MOM capacitors and a charge pump with complimentary MOS capacitors. As shown in FIG. 6, the output voltage versus number of cycles for the MOM capacitor charge pump 602 and complimentary MOS capacitor charge pump 604 are nearly identical. Thus, replacing MOM capacitors with complimentary MOS capacitors, such as the example illustrated in FIG. 5A, offer benefits. For example, as shown in FIG. 6, a Dickson charge pump circuit implemented with the complimentary MOS capacitors can obtain nearly the same performance as one implemented with a MOM capacitor. Also, the complimentary MOS capacitors are much smaller that a MOM capacitor resulting in large area savings in an IC. For example, a four stage Dickson charge pump circuit implemented with complimentary MOS capacitors can result in an area reduction of approximately 10 times compared with a MOM implementation while maintaining similar performance. It is also noted that one or more, or all, of the MOM capacitors of an example charge pump can be replaced with complimentary MOS capacitors.

The space saving and performance of a charge pump implemented with complimentary MOS capacitors can be beneficial in many types of circuits. For example, in a memory cell that needs a reference voltage, such as a compute in memory (CIM) memory cell, the size reduction of a charge pump can facilitate the charge pump fitting within the columns of a memory cell array.

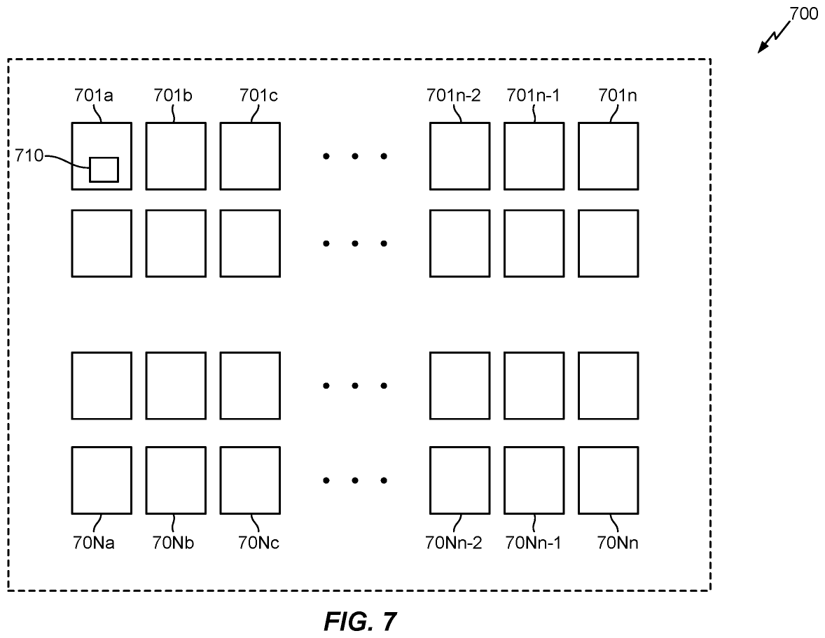

FIG. 7 illustrates a memory array 700. The memory array 700 includes a plurality of memory cells 701a-70Nn. At least some of the memory cells can be a “standard” or the same size to make more efficient use of the area used for the memory array and ease connection routing. At least some of the memory cells can include additional circuitry 710 that can perform computations in the memory cell, referred to as compute in memory. Performing computations in memory cells can reduce the amount of data transferred to and from the memory. The computations can be analog or digital. In one example a reference voltage may be needed for a computation in memory and a charge pump using complementary MOS capacitors may be included in the circuitry 710 included in a memory cell.

Additionally, a charge pump implemented using complimentary MOS capacitors can provide reference voltage in CPUs, GPUs, SoC, mobile chips, and other devices.

While the description has used a charge pump as an example circuit illustrating the benefits of complimentary MOS capacitors other circuits can also benefit from the improved linearity and size reduction. Any circuit can use complimentary MOS capacitors in place of linear capacitors, such as MOM or MIM capacitors. For example, an analog to digital converter (ADC) circuit can use complimentary MOS capacitors.

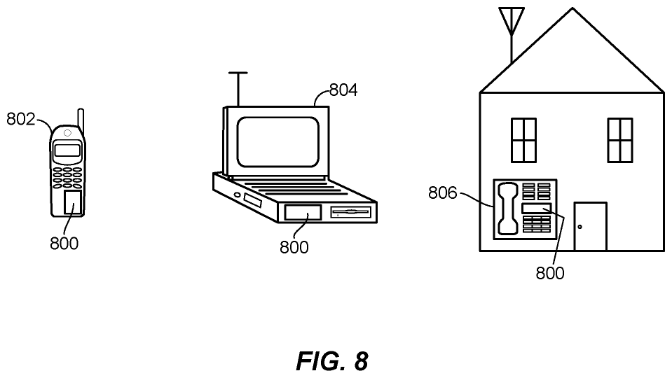

FIG. 8 illustrates various electronic devices that may be include a complimentary MOS capacitor. For example, a mobile phone device 802, a laptop computer device 804, a terminal device 806 as well as wearable devices, portable systems, that require small form factor may include an apparatus 800 that incorporates the devices/systems as described herein. The apparatus 800 may be, for example, any of the integrated circuits, dies, integrated devices, integrated device packages, integrated circuit devices, device packages, integrated circuit (IC) packages, package-on-package devices, system-in-package devices described herein. The devices 802, 804, and 806 illustrated in FIG. 8 are merely exemplary. Other electronic devices may also feature the apparatus 800 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), or any other device that stores or retrieves data or computer instructions, or any combination thereof.

The various illustrative modules and circuits described in connection with the aspects disclosed herein may be implemented or performed in an integrated circuit (IC), a system on a chip (SoC), an Application Specific Integrated Circuit (ASIC), a Field Programmable Gate Array (FPGA) or other programmable logic device, discrete gate or transistor logic, discrete hardware components, or any combination thereof designed to perform the functions described herein.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but is to be accorded the widest scope consistent with the principles and novel features disclosed herein.

What is claimed is:

1. A complimentary metal-oxide-silicon (MOS) capacitor comprising:
an n-type MOS capacitor; and
a p-type MOS capacitor coupled in parallel with the n-type MOS capacitor, wherein the p-type MOS capacitor is biased to an opposite voltage polarity of the n-type MOS capacitor.

2. The complimentary MOS capacitor of claim 1, further comprising:
a source and a drain of the p-type MOS capacitor coupled to a bias voltage source.

3. The complimentary MOS capacitor of claim 1, further comprising a voltage source coupled to the gate of the n-type MOS capacitor and the gate of the p-type MOS capacitor.

4. The complimentary MOS capacitor of claim 1, wherein the complimentary MOS capacitor is in a memory cell.

5. The complimentary MOS capacitor of claim 4, wherein the memory cell is a compute in memory (CIM) memory cell.

6. A charge pump circuit comprising:
a plurality of MOS transistors configured as diodes, the plurality of MOS transistors coupled in series;
a complimentary MOS capacitor coupled between a node of one of the MOS transistors and a clock signal.

7. The charge pump circuit of claim 6, wherein the complimentary MOS capacitor comprises:
a n-type MOS capacitor; and
a p-type MOS capacitor coupled in parallel with the n-type MOS capacitor, wherein the p-type MOS capacitor is biased to an opposite voltage polarity of the n-type MOS capacitor.

8. The charge pump circuit of claim 7, further comprising:
a source and a drain of the p-type MOS capacitor coupled to a bias voltage source.

9. The charge pump circuit of claim 7, further comprising a voltage source coupled to a gate of the n-type MOS capacitor and a gate of the p-type MOS capacitor.

10. The charge pump circuit of claim 6, further configured to be in a memory cell.

11. The charge pump circuit of claim 10, wherein the memory cell is a compute in memory (CIM) memory cell.

12. The charge pump circuit of claim 6, wherein the plurality of MOS transistors comprises:
five MOS transistors configured as five diodes, the five diodes coupled in series such that a cathode of the first diode is coupled to a anode of the second diode, a cathode of the second diode is coupled to a anode of the third diode, a cathode of the third diode is coupled to a anode of the fourth diode, and a cathode of the fourth diode is coupled to a anode of the fifth diode.

13. The charge pump of claim 12, further comprising:
a first complimentary MOS capacitor coupled between a cathode of the first diode and a clock signal and a third complimentary MOS capacitor coupled between a cathode of the third diode and the clock signal;
a second complimentary MOS capacitor coupled between a cathode of the second diode and a clock_bar signal and a fourth complimentary MOS capacitor coupled between a cathode of the fourth diode and the clock_bar signal;
a fifth complimentary MOS capacitor coupled between the cathode of the fifth diode and ground; and
an input signal coupled to the anode of the first diode and an output signal coupled to the cathode of the fifth diode.

14. The charge pump circuit of claim 12, further configured to be in a memory cell.

15. The charge pump circuit of claim 14, wherein the memory cell is a compute in memory (CIM) memory cell.
